(19) United States
(12) Patent Application Publication
(10) Pub. No.: US 2007/0111469 A1
(43) Pub. Date: May 17, 2007

(54) Method for fabricating semiconductor device with bulb-shaped recess gate

(75) Inventors: Sei-Jin Kim, Ichon-shi (KR); Ki-Won Nam, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/477,536

(22) Filed: Jun. 30, 2006

(30) Foreign Application Priority Data
Nov. 16, 2005 (KR) 2005-0109554

(51) Int. Cl. H01L 21/76

(52) U.S. Cl. 438/424

(57) ABSTRACT

A method for fabricating a semiconductor device includes: forming a pad oxide layer over a substrate; forming a hard mask pattern over the pad oxide layer; etching a predetermined portion of the pad oxide layer and the substrate using the hard mask pattern to form a first recess having sidewalls and a bottom portion; forming a spacer over the hard mask pattern and on the sidewalls and the bottom portion of the first recess; and etching the substrate beneath the first recess using the spacer as an etch barrier to form a second recess, the second recess being wider and more rounded than the first recess.

### RELATED APPLICATION

The present application is based upon and claims benefit of priority to Korean patent application No. KR 2005-0109554, filed in the Korean Patent Office on Nov. 16, 2005, the entire contents of which are incorporated herein by reference.

### TECHNICAL FIELD

The present invention relates to a method for fabricating a semiconductor device; and more particularly, to a method for fabricating a semiconductor device with a bulb-shaped recess gate.

### DESCRIPTION OF RELATED ARTS

As for a typical method for forming a planar gate interconnection line by forming a gate over a flat active region, the current large integration scale of semiconductor devices has caused a channel length to be decreased but an implantation doping concentration to be increased. Accordingly, due to an increased electric field, a junction leakage is generated and thus, it becomes difficult to secure a satisfactory refresh property of a device.

A recess gate process forming a gate after etching a substrate defined into an active region in a recess pattern is implemented as a method for forming a gate interconnection line to solve the aforementioned problems. If the recess gate process is used, a channel length can be increased and an implantation doping concentration can be decreased. As a result, a refresh property of the device can be improved.

FIG. 1 is a cross-sectional view illustrating a recess gate structure of a semiconductor device formed by a typical recess gate process.

Referring to FIG. 1, predetermined portions of a substrate 11 are etched to form a plurality of recesses 12. A gate insulation layer 13 is formed over the entire surface of the substrate 11 where recesses 12 are formed.

A plurality of gate patterns 14 are formed over the gate insulation layer 13. Particularly, first portions of gate patterns 14 are buried in the recesses 12, and second portions of gate patterns 14 project above the surface of the substrate 11. Each of the gate patterns 14 includes a bottom electrode 14A formed of polysilicon, and a top electrode 14B formed of tungsten silicide (WSi).

An alignment failure 100 may occur between the gate patterns 14 and the recesses 12.

For a semiconductor device having a pattern size of 80 nm, a width of a recess gate is generally 53 nm. Thus, an alignment margin between a recess structure and a gate electrode is only approximately 16 nm. If an overlay is missed by approximately 10 nm or more, an alignment failure may occur. Also, during the etching for forming the gate, polysilicon residues may remain, as a result of which subsequent structure may be damaged or a gap-filling may not be performed properly, and a void may be formed.

Furthermore, lengthening a channel is generally required to improve a refresh property of a typical ‘U’ shaped recess pattern. However, it may be difficult to lengthen the channel since an etched depth of the recess cannot be increased due to limitations associated with ion implantation processes and a recess etching process for forming the channel.

### SUMMARY

Disclosed is a method for fabricating a semiconductor device with a bulb-shaped recess gate capable of improving an overlay margin, and a refresh property.

A method for fabricating a semiconductor device consistent with the present invention includes forming a pad oxide layer over a substrate; forming a hard mask pattern over the pad oxide layer; etching a predetermined portion of the pad oxide layer and the substrate using the hard mask pattern to form a first recess having sidewalls and a bottom portion; forming a spacer over the hard mask pattern and on the sidewalls and the bottom portion of the first recess; and etching the substrate beneath the first recess using the spacer as an etch barrier to form a second recess, the second recess being wider and more rounded than the first recess.

### BRIEF DESCRIPTION OF THE DRAWINGS

The above and other features of the present invention will become better understood with respect to the following description of the exemplary embodiments given in conjunction with the accompanying drawings, in which:

FIG. 1 is cross-sectional view illustrating a typical semiconductor device; and

FIGS. 2A to 2F are cross-sectional views illustrating a method for forming a semiconductor device consistent with the present invention.

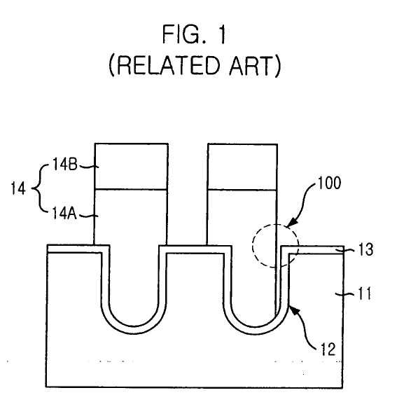

### DETAILED DESCRIPTION

Hereinafter, detailed descriptions on certain embodiments of the present invention will be provided with reference to the accompanying drawings.

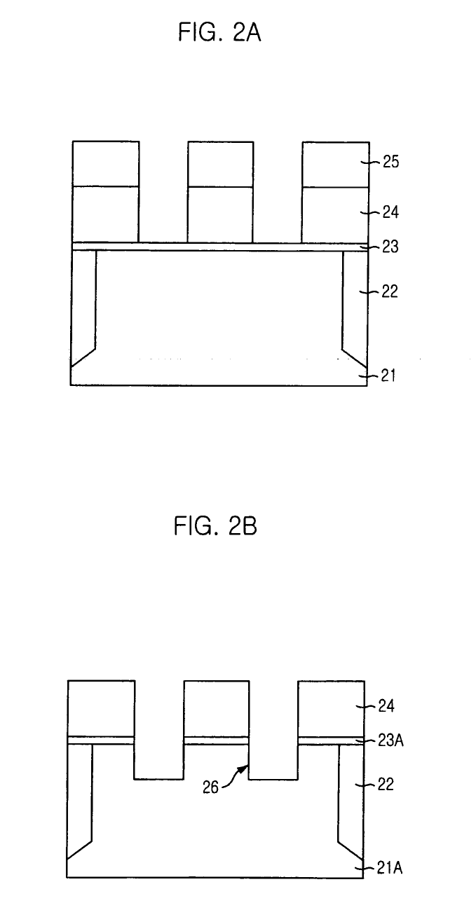

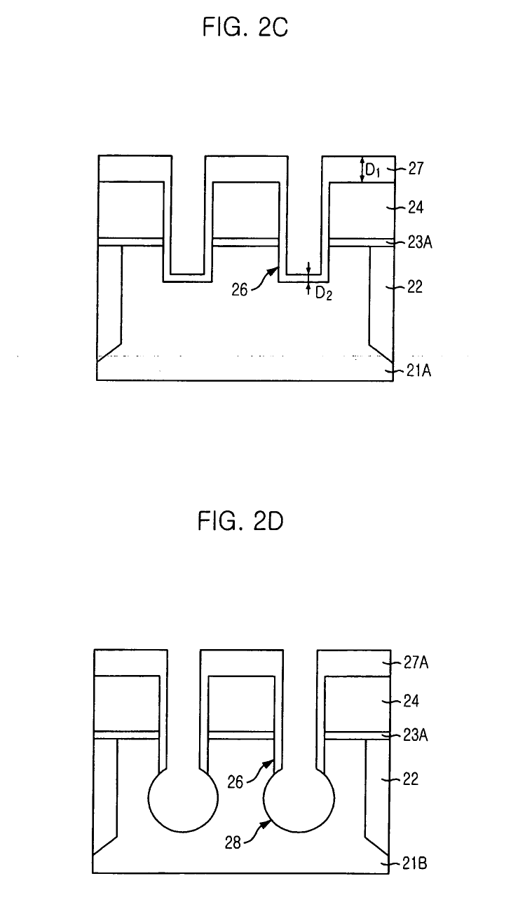

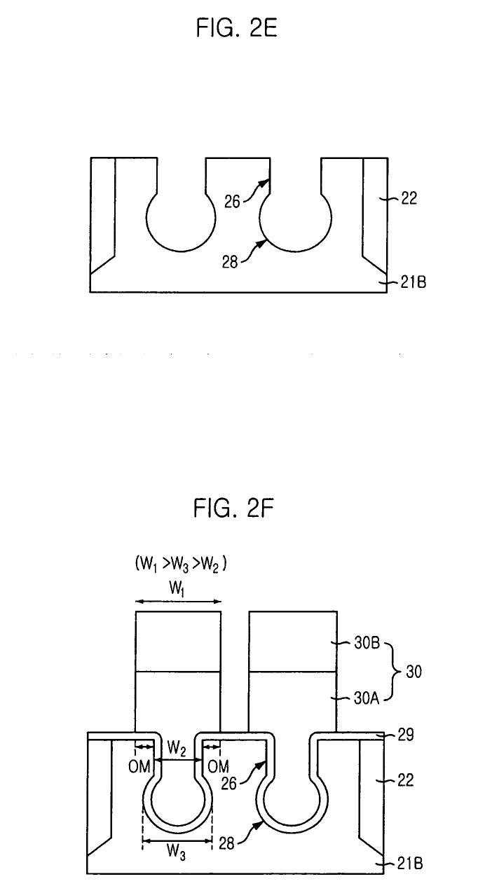

FIGS. 2A to 2F are cross-sectional views illustrating a method for fabricating a semiconductor device consistent with the present invention.

As shown in FIG. 2A, a plurality of device isolation layers 22 are formed in a substrate 21 to define an active region. The device isolation layers 22 may have a depth of approximately 3,000 Å.

In more detail of the formation of the device isolation layers 22, predetermined portions of the substrate 21 are etched to form trenches. An insulation layer is filled into the trenches, and a chemical mechanical polishing (CMP) process is performed to planarize the insulation layer, thereby forming the device isolation layers 22.

Next, a pad oxide layer 23 is formed over the device isolation layers 22. A hard mask pattern 24 and a patterned photoresist layer 25 are formed over the pad oxide layer 23.

Although not shown, the steps of forming the hard mask pattern 24 and the patterned photoresist layer 25 will be explained hereinafter.

A hard mask is formed over the pad oxide layer 23. Herein, the hard mask serves to secure a margin of a photoresist layer during a subsequent etching of the substrate 21. The hard mask is formed of polysilicon to a thickness ranging from approximately 1,800 Å to approximately 2,000 Å.

A photoresist layer is formed over the hard mask and then, is patterned through a photolithography process to form the patterned photoresist layer 25. The photoresist layer is patterned to have openings with a width smaller than that of a typical photoresist pattern opening by at least approximately 10 nm or more. For instance, if the typical photoresist pattern opening has a width of approximately 53 nm, the photoresist layer is patterned to have openings with a width approximately 43 nm or less by patterning the photoresist layer smaller by approximately 10 nm or more consistent with the present invention.

The hard mask is etched using the patterned photoresist layer 25 as an etch mask to form the hard mask pattern 24. The hard mask is patterned using the patterned photoresist layer 25 and thus, an overlay margin with respect to a subsequent gate pattern can be secured.

As shown in FIG. 2B, the patterned photoresist layer 25 is removed using oxygen plasma.

Predetermined portions of the pad oxide layer 23 and the substrate 21 are simultaneously etched using the hard mask pattern 24 as an etch mask to form a plurality of first recesses 26. Reference numerals 23A and 21A denote the patterned pad oxide layer and the patterned substrate, respectively. Each of the first recesses 26 is formed to a thickness ranging from approximately 500 Å to approximately 600 Å.

As shown in FIG. 2C, a spacer layer 27 is formed over surfaces of the first recesses 26, the hard mask pattern 24, and the patterned pad oxide layer 23.

The spacer layer 27 is formed to protect sidewalls of the first recesses 26 during a subsequent process of forming second recesses. The spacer layer 27 is formed of undoped silicate glass (USG) oxide layer through a plasma enhanced chemical vapor deposition (PECVD) method at a temperature ranging from approximately 390° C. to approximately 410° C. and a pressure ranging from approximately 2.1 Torr to approximately 2.5 Torr. Because the spacer layer 27 is formed of the USG oxide layer having low step coverage, a thickness D₁ of the spacer layer 27 over the top surface of the hard mask pattern 24 is greater than a thickness of the spacer layer 27 on sidewalls of the hard mask pattern 24 and a thickness D₂ of the spacer layer 27 over a surface of the patterned substrate 21A beneath the first recesses 26. In one aspect, a portion of the spacer layer 27 over the top surface of the hard mask pattern 24 has a thickness ranging from approximately 250 Å to approximately 350 Å.

As shown in FIG. 2D, the patterned substrate 21A beneath the first recesses 26 is etched using the hard mask pattern 24, the patterned pad oxide layer 23A, and the spacer layer 27 as an etch mask to form a plurality of second recesses 28. The resultant, further patterned substrate is denoted with a reference numeral 21B. The second recesses 28 are wider and more rounded than the first recesses 26.

The second recesses 28 are formed using an isotropic dry etching process. The isotropic dry etching process is performed with an etch selectivity of silicon to an oxide layer being approximately 2:1. The isotropic dry etching process is performed using a mixture gas of chlorine (Cl₂) and hydrogen bromide (HBr) at a pressure of at least approximately 500 mTorr or more.

Recesses including the first recesses 26 having a vertical etch profile and the second recesses 28 having a rounded etch profile are referred to as bulb-shaped recesses. Each of the bulb-shaped recesses has a channel longer than a typical ‘U’ shaped recess.

During the isotropic dry etching process to form the second recesses 28, predetermined portions of the spacer layer 27 formed over the hard mask pattern 24 may be etched. However, since the spacer layer 27 is formed with low step coverage, i.e., a thickness of the spacer layer 27 is the greatest over the surface of the hard mask pattern 24, the spacer layer 27 partially remains as spacers 27A over the surface of the hard mask pattern 24 even after the second recesses 28 are formed. The spacers 27A serve as an etch barrier.

As shown in FIG. 2E, the hard mask pattern 24 and the spacers 27 over the hard mask pattern 24 are removed. Etch residues, the patterned pad oxide layer 23A, and the spacers 27A remaining over the sidewalls of the first recesses 26 are also removed.

In more detail of the removal of the residues, the patterned pad oxide layer 23A, and the patterned spacers 27A, a cleaning process is performed using one of hydrogen fluoride (HF) solution and buffered oxide etchant (BOE).

As shown in FIG. 2F, a gate insulation layer 29 is formed over the further patterned substrate 21B including the bulb-shaped recesses including the first recesses 26 and the second recesses 28.

A plurality of gate patterns 30 having first portions filled into the bulb-shaped recesses and second portions projected above the further patterned substrate 21B are formed over the gate insulation layer 29. Each of the gate patterns 30 is formed by sequentially stacking a gate electrode 30A and a gate hard mask 30B. The gate electrode 30A includes a stack structure of polysilicon and tungsten silicide (WSiₓ), and the gate hard mask 30B includes silicon nitride (Si₃N₄).

As described above, a width W₂ of the respective first recess 26 is smaller than a typical width by at least approximately 10 nm or more, and a width W₃ of the respective second recess 28 formed by the isotropic etching process is similar to a typical width since the substrate is also etched from the side due to the isotropic etching process.

Accordingly, the width W₂ of the respective first recess 26 is smaller than a width W₁ of the respective gate pattern 30 and a margin OM sufficient to prevent a misalignment can be secured. Also, since the width W₃ of the respective second recess 28 is similar to a typical width, a channel length is longer than that in a typical “U” shaped recess gate.

Consistent with the present invention, a margin of at least 10 nm or more is provided so that misalignment between a first recess and a gate pattern can be prevented. Also, a pointed shaped structure in a bottom portion of an active region can be removed and a bulb-shaped recess can be formed by performing an isotropic etching process during forming a second recess. Accordingly, a channel length can be increased and a refresh property can be improved. Yields of products can be improved, and a cost can be reduced.

While the present invention has been described with respect to certain embodiments, it will be apparent to those skilled in the art that various changes and modifications may be made without departing from the spirit and scope of the invention as defined in the following claims.

What is claimed is:

1. A method for fabricating a semiconductor device, comprising:
forming a pad oxide layer over a substrate;
forming a hard mask pattern over the pad oxide layer;
etching a predetermined portion of the pad oxide layer and the substrate using the hard mask pattern to form a first recess having sidewalls and a bottom portion;
forming a spacer over the hard mask pattern and on the sidewalls and the bottom portion of the first recess; and
etching the substrate beneath the first recess using the spacer as an etch barrier to form a second recess, the second recess being wider and more rounded than the first recess, the second recess and the first recess constituting a third recess.

2. The method of claim 1, further comprising, after forming the second recess:
removing the spacer remaining over the hard mask pattern and on the sidewalls of the first recess; and
forming a gate pattern over the third recess.

3. The method of claim 2, wherein forming the spacer comprises forming the spacer to be thicker over a top portion of the hard mask pattern than on the sidewalls of the first recess.

4. The method of claim 3, wherein forming the spacer comprises forming the spacer to be thicker over the top portion of the hard mask pattern than over the bottom portion of the first recess.

5. The method of claim 4, wherein forming the spacer comprises forming an undoped silicate glass (USG) oxide layer.

6. The method of claim 5, wherein forming the spacer comprises performing a plasma enhanced chemical vapor deposition (PECVD) method.

7. The method of claim 6, wherein forming the spacer uses a pressure ranging from approximately 2.1 Torr to approximately 2.5 Torr and a temperature ranging from approximately 390° C. to approximately 410° C.

8. The method of claim 7, wherein forming the spacer comprises forming the spacer a thickness ranging from approximately 250 Å to approximately 350 Å over the top portion of the hard mask pattern.

9. The method of claim 1, wherein forming the second recess comprises performing an isotropic etching process.

10. The method of claim 9, wherein forming the second recess comprises performing the isotropic etching process with an etch selectivity of silicon to an oxide layer being approximately 2:1.

11. The method of claim 10, wherein performing the isotropic etching process uses a mixture gas including chlorine (Cl₂) and hydrogen bromide (HBr).

12. The method of claim 11, wherein performing the isotropic etching process uses a pressure of at least approximately 500 mTorr.

13. The method of claim 1, wherein forming the first recess comprises forming the first recess to a thickness ranging from approximately 500 Å to approximately 600 Å.

14. The method of claim 2, wherein removing the spacer remaining over the sidewall of the first recess comprises performing a cleaning process using one of a hydrogen fluoride (HF) solution and buffered oxide etchant (BOE).

15. The method of claim 1, wherein forming the hard mask pattern comprises:
sequentially forming a hard mask layer and a photoresist layer over the gate oxide layer;
patterning the photoresist layer through a photolithography process;
etching the hard mask layer using the patterned photoresist layer as an etch mask; and
removing the patterned photoresist layer.

16. The method of claim 15, wherein forming the hard mask pattern comprises forming the hard mask pattern to a thickness ranging from approximately 1,800 Å to approximately 2,000 Å.

17. The method of claim 1, wherein the third recess has a bulb shape.
